(19) United States
(12) Patent Application Publication
(10) Pub. No.: US 2005/0089767 A1
(43) Pub. Date: Apr. 28, 2005

(54) Mask for off axis illumination and method for manufacturing the same

(76) Inventor: Chung-Hsing Chang, Hong Kong (HK)

Correspondence Address: RABIN & BERDO, P.C., Suite 500, 1101 14 Street, N.W., Washington, DC, 20005, US

(21) Appl. No.: 10/922,898

(22) Filed: Aug. 23, 2004

Related U.S. Application Data
(60) Provisional application No. 60/496,992, filed on Aug. 22, 2003.

(51) Int. Cl. G03C 5/00; G03F 9/00

(52) U.S. Cl. 430/5; 430/322; 430/394

(57) ABSTRACT

A mask used to form contact holes of 90 nm, 65 nm, and beyond, and methods of forming the mask. The mask comprises a mask substrate and at least one pattern on the mask substrate. The pattern includes a square opening formed as the center of a square, four square holes formed at the corners of the square, and four anti-scattering bars formed around the square opening. Each of those bars is located between two square holes and in the middle of one edge of the square. A layer of opaque material is formed on the spacing between the square opening, the anti-scattering bar and the square hole.

### CROSS-REFERENCE TO RELATED APPLICATION

This application claims the benefit of U.S. Provisional application No. 60/496,992, filed Aug. 22, 2003.

### BACKGROUND OF THE INVENTION

1. Field of Invention

The invention relates to integrated circuit fabrication, and more particularly to a phase shifting mask used in a photolithography process and a method of photomask manufacturing thereof.

2. Discussion of the Related Art

In the semiconductor industry, there is a continuing effort to increase device density by scaling down the device dimensions. Conventionally, to form an integrated circuit, a resist layer is formed on a wafer and is exposed to radiation through a photomask (“mask”). A mask typically comprises a substantially transparent base material such as quartz with an opaque layer having a desired pattern formed thereon. For example, chrome has long been used to make the opaque layer. When device features are reduced to a dimension below the sub-micro level, diffraction effects become significant. The blending of two diffraction patterns associated with features which are close to one another has an adverse effect on resolution because portions of the resist layer underlying the opaque layer near the edges of features are exposed.

To minimize effects of diffraction, various kind of phase shifting masks have been used. Typically, a phase shifting mask has a pattern in the opaque layer such as chrome for transmitting exploring radiation which corresponds to the pattern to be formed on the underlying resist layer. Also, phase-shifters, which transmit the incident radiation and shift the phase of the radiation approximately 180 degrees, are added onto the mask reduce diffraction effects. Alternate aperture phase shifting masks are formed by adding phase-shifters over every opening. In rim phase shifting masks, phase-shifters are added along or near the outer edges of the features. The radiation transmitted through the phase-shifter interferes with radiation from the features, thereby reducing the intensity of incident radiation on the resist material underlying the opaque layer near a feature edge to improve image resolution.

The conventional approach to improving the resolution is increasing the numerical aperture (NA) of the projection lens. However, the problem of smaller depth of focus (DOF) arises and increases the difficulty for LSI (large-scale integration) mass production. Many resolution enhancement techniques (RETs) are proposed to extend the resolution limit of optical lithography, while simultaneously providing enough DOF. Among these, off-axis illumination technologies and phase-shifting mask technologies (PSMs) are the most feasible methods to be compatible with the present manufacturing infrastructure. However, the dependence of DOF on pattern duty limits RETs applicable to only a certain range of pitch values.

Therefore, large depth of focus (DOF) is required in projection optical lithography to overcome process issues like uneven surface of a device and focus adjustment error. Phase-shifting masks (PSMs) are popular super resolution techniques to retain relatively large DOF while increasing the numerical aperture (NA) for higher resolution capability at a fixed wavelength.

For contact hole printing, the PSMs often have symmetrical phase-shifted assist features surrounding the main feature opening. An outrigger design in Levenson-type PSMs and a rim-phase shifter design with different transmission in attenuated PSMs have been applied to deep sub-micron contact printing used in today's workhorse DUV wavelength exposure machines. As explained by Hiroshi Fukuda (published in J. Appl. Phys. 32 (1991) 3037, J. Appl. Phys. 32 (1993) 5845), the contact holes PSM design is based on the principle of approximating the inverse Fourier transform of an apodized pupil function.

The optimization of exposure conditions, with the aim of maximizing common windows for all layout features, is particularly complicated due to contradictory conditions required by isolated, semi-isolated and dense contact holes: a small partial coherence value provides good results on isolated features, while large partial coherence and off-axis illumination are required to achieve sufficient resolution for printing dense contact holes. So the problem that must be solved in order to achieve a single exposure low k1 contact holes imaging through pitch is to discover a way to print dense contact holes array with conventional illumination (small sigma) or discover a way to print isolated and semi-isolated contact holes with strong off-axis illumination.

Therefore there is a need to develop a new phase-shifting mask illuminated by off-axis illumination to have better DOF, image contrast and resolution for better lithographic performance.

### SUMMARY OF THE INVENTION

In order to solve the aforementioned problems, we combine the advantages of phase-shifting with off-axis illumination (OAI) to design a mask pattern for contact holes. Through the designed pattern of the mask (called New and Improved Contact-hole pattern Exposure PSM—NICE PSM) and an OAI aperture illuminator (ex: QUASAR), DOF, image contrast and resolution of lithographic performance are improved for deep sub-micron through pitch contact holes patterning. By using this novel mask design, “Apodizing” diffraction distribution (Fourier transform pattern produced by passing light through the mask) is projected on the pupil plane and forms a natural pupil filter. Next, if there is an appropriate illuminator with which to collocate, the DOF of the process window for isolated and semi-isolated pitch contact holes pattern can be simultaneously enhanced.

In view of the foregoing, an objective of the invention is to provide a mask with at least one pattern having regions producing a phase shift of approximately 180 degrees and regions producing a non-phase shift (0 degree) while allowing light to pass through.

Another objective of the invention is to provide a mask having at least one pattern comprising four square contact holes at the corners of a square to produce phase shifting (180 degree), and a square opening at the center of the square and four anti-scattering bars around the central square opening to produce non-phase shifting (0 degree).

Another objective of the invention is to provide a method of forming a mask having four square holes at the corners of a square, a square opening at the center of the square and four anti-scattering bars around the central square opening. Each of the anti-scattering bars is located between two square contact holes and is co-liner with them.

Another objective of the invention is to provide a method of exposing a photo-resist layer on a substrate using off-axis illumination of a mask having four square holes at the corner of a square, four square openings at the middle of the edge of the square and one square opening located at the center of it.

To achieve the above objectives, the disclosed mask contains: a mask substrate; at least one pattern on the mask substrate, including: a square opening formed as a center of a square, four square holes formed at the corners of the square, and four anti-scattering bars formed around the square opening; each of the anti-scattering bars is located between two square holes and in the middle of one edge of the square; a layer of opaque material formed in a spacing between the square opening, the anti-scattering bar and the square hole.

To achieve the above objectives, the disclosed method of forming the mask includes: providing a mask substrate; forming a layer of opaque material on the mask substrate; patterning the opaque material; forming a square opening as the center of a square and four anti-scattering bars around the square opening, with each of the anti-scattering bars located in the middle of one edge of the square; patterning the mask substrate; and forming four square holes at the corners of the square.

The mask is then used in a projection system to form an image of the mask on an integrated circuit wafer having a photo-resist layer formed thereon. The mask is illuminated using off-axis illumination and the light passing through the mask is focused on the photo-resist layer formed on the integrated circuit wafer.

It is to be understood that both the foregoing general description and the following detailed description are exemplary and explanatory, and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention.

FIG. 1 shows a 3D structure of the mask of the invention;

FIG. 2 shows a cross-sectional view of the mask taken along line I-I of FIG. 1;

FIG. 3 shows a schematic diagram of an optical projection system used to expose a photo-resist layer in an integrated circuit wafer with the mask pattern;

FIG. 4 shows an aperture used for dipole off-axis illumination of a mask;

FIG. 5A shows a cross-sectional view of a mask substrate with a layer of opaque material and a photo-resist layer formed thereon;

FIG. 5B shows a cross-sectional view of the mask of FIG. 5A after the first photo-resist layer has been exposed and developed;

FIG. 5C shows a cross-sectional view of the mask of FIG. 5B after the layer of opaque material has been etched;

FIG. 5D shows a cross-sectional view of the mask of FIG. 5C after the first photo-resist layer has been removed;

FIG. 5E shows a cross-sectional view of the mask of FIG. 5D with a patterned layer of opaque material and a second photo-resist layer formed thereon;

FIG. 5F shows a cross-sectional view of the mask of FIG. 5E after the second photo-resist layer has been exposed and developed;

FIG. 5G shows a cross-sectional view of the mask of FIG. 5F after the mask substrate has been etched;

FIG. 5H shows a cross-sectional view of the mask of FIG. 5G after the second photo-resist layer has been removed; and

FIG. 6 shows aerial images of simulation for an isolated pattern of the mask of the invention; and

FIG. 7A shows the pattern of the mask of the invention;

FIG. 7B shows the Fourier Transform distribution image of the mask of the FIG. 7A; and

FIG. 7C shows the cross-section view of the simulation of Fourier Transform distribution of the mask.

### DETAILED DESCRIPTION OF THE INVENTION

For contact hole printing, the main concept of the invention to expose contact holes combines proper phase assignment and design with an applicable illuminator to modify the pattern of a mask to produce apodizing diffraction distribution on a pupil plane (analogous with natural pupil filtering) instead of using a real pupil filtering lens. By using this novel mask design, “Apodizing” diffraction distribution (Fourier transform pattern produced by passing light through the mask) is projected on the pupil plane and forms a natural pupil filter. In other words, it has the same effect as a natural pupil filter or even better. Next, if there is an appropriate illuminator (e.g. off-axis illumination (OAI)) with which to collocate, the DOF of the process window for isolated and semi-isolated pitch contact holes pattern can be enhanced.

Therefore, according to the concept described above, at least one mask pattern producing a phase shift region of approximately 180 degrees and non-phase shifting (0 degree) in the pupil plane from the mask substrate is disclosed. This means that the pattern of the mask comprises phase shifting (180 degree) regions and non-phase shifting (0 degree) regions. The phase shifting (180 degree) regions include four square contact holes at the corners of a square and the non-phase shifting (0 degree) regions include a square opening at the center of the square and four anti-scattering bars around the central square opening. Each of the anti-scattering bars is located between two square contact holes and is co-liner with them.

By the pattern of the mask described above, a diffraction distribution with four 180 degree phases shifting and five 0 degree phases shifting can be produced in the pupil plane.

According to the phase shifting in the image produced by using the pattern of the mask designed to allow off-axis illumination light to pass through, better exposure energy latitude, larger depth of focus and better contrast image of contact holes pattern on the semiconductor substrate can be produced.

The design of the mask pattern depends on the numerical aperture of the optical system, light wavelength, and the angle of incident off-axis illumination of the exposure illuminator.

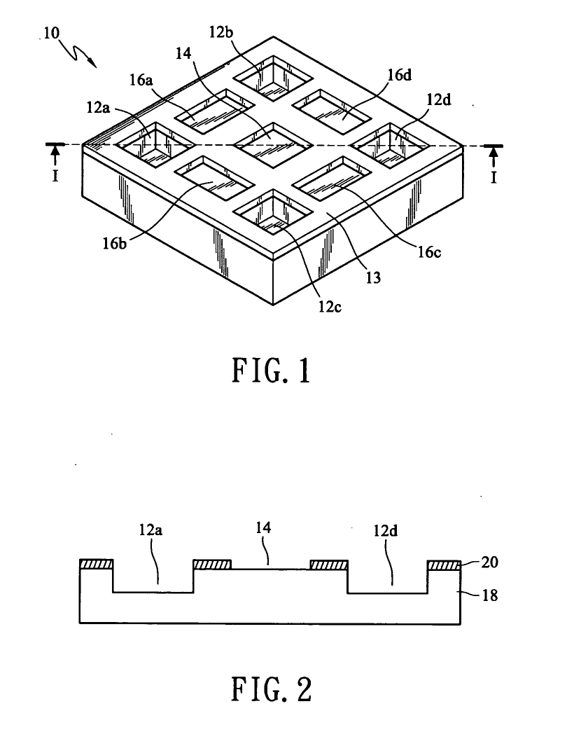

Refer now to FIG. 1 for a description of the preferred embodiments of the mask of the invention. FIG. 1 shows a 3D structure of the mask of the invention. FIG. 2 shows a cross-sectional view of the mask taken along line I-I of FIG. 1. The mask has at least one pattern region 10 where the four square holes 12a, 12b, 12c, and 12d are located away from the center. The square holes 12a, 12b, 12c, and 12d are all an equal distance away from the center and are located at four corners of the square. Furthermore, the mask has anti-scattering bars 16a, 16b, 16c, and 16d between every two square holes. Each anti-scattering bar and the two square corners are co-liner with one another and are along with the edge of the square (e.g. anti-scattering bar 16a and square holes 12a, 12b). The mask also has a square opening 14 located at the center of the square. The four square holes 12a, 12b, 12c, and 12d are formed by etching away the mask substrate and each of the anti-scattering bars 16a, 16b, 16c, and 16d and the central square opening 14 are transparent. As showed in FIG. 2, the rest of the pattern region is opaque. In other words, the spacings between anti-scattering bars 16a, 16b, 16c, and 16d, the square opening and the square holes 12a, 12b, 12c, and 12d are opaque 13.

The mask provides four square holes 12a, 12b, 12c, and 12d at the corners of a square, four anti-scattering bars 16a, 16b, 16c, and 16d between the square holes 12a, 12b, 12c, and 12d respectively, and one square opening 14 located at the center of the square on the same mask. The four square holes 12a, 12b, 12c, and 12d are formed by etching part of the mask substrate away to allow light to pass through. The square opening 14 and anti-scattering bars 16a, 16b, 16c, and 16d are formed by removing the opaque layer formed on the mask substrate. The mask design data is used to determine which sections of the mask are formed with square holes and which sections of the mask have square openings formed without opaque material. In order to obtain good resolution and depth of focus in the region, the mask is illuminated using off-axis illumination.

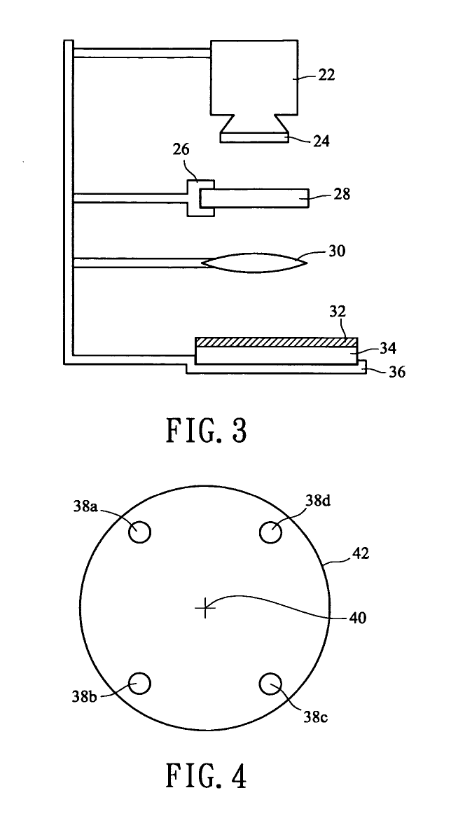

Refer to FIG. 3. FIG. 3 shows a schematic diagram of an optical projection system used to expose a photo-resist layer in an integrated circuit wafer with the mask pattern. FIG. 3 shows a light source 22, an exit aperture 24 from the light source 22, a means 26 for holding the mask 28, a lens 30 to focus the light passing through the mask 28, and a wafer holder 36 holding an integrated circuit wafer 34 with a photo-resist layer 32 formed thereon. As shown in FIG. 1, the mask 28 is between the exit aperture 24 and the lens 30, and the lens 30 is between the mask 28 and the photo-resist layer 32 on the integrated circuit wafer 34. In order to illuminate the mask 28, the light must pass through the exit aperture 24. The diffraction distribution is produced in the pupil plane between the mask 28 and the lens 30 while a light is illuminating the mask 28. The mask 28 is the mask descried above having the pattern of a mask substrate.

In this example, off-axis illumination is used for illuminating the mask 28. The preferred exit aperture 24 used is shown in FIG. 4, which shows an opaque panel 42 with four openings 38a, 38b, 38c, and 38d located away from the optical axis 40 and located at four corners of the square. This exit aperture 24 provides quadrapole off-axis illumination for the mask 28.

The preferred exit aperture above can be QUASAR off-axis illumination. The QUASAR off-axis illumination can be used as a DOE (Diffractive Optical Element). The QUASAR off-axis illumination can be used as a binary mask type Aperture to illuminate the mask.

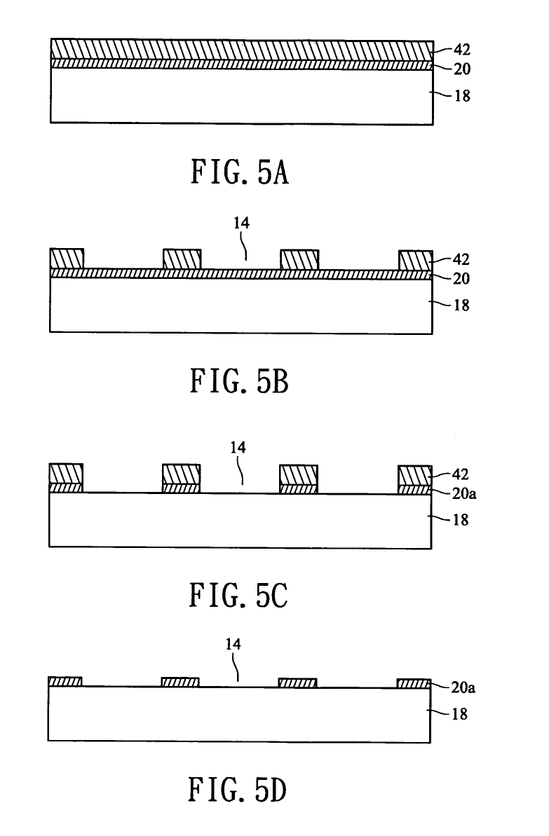

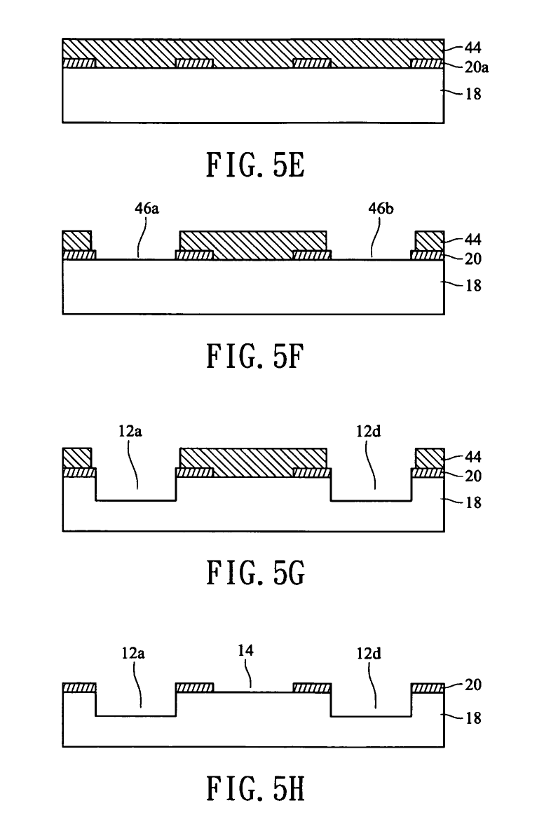

Refer now to FIGS. 5A-5H for the preferred embodiment of a method of manufacturing the mask of the invention.

FIG. 5A shows a cross-sectional view of a mask substrate with a layer of opaque material and a photo-resist layer formed thereon. A layer of opaque material 20, such as chrome, is deposited on the mask substrate 18. A first photo-resist layer 42 is deposited on the layer of opaque material 20.

The mask substrate is made of transparent material, such as quartz.

FIG. 5B shows a cross-sectional view of the mask of FIG. 5A after the first photo-resist layer 42 has been exposed and developed. As shown in FIG. 5B, the first photo-resist layer 42 is then developed. The exposure of the first photo-resist layer 42 is such that after developing the first photo-resist layer, the pattern is formed exposing four anti-scattering bars in the middle of the edge of the square, a square opening 14 at the center of the square and/or the square holes at the corners of the square.

The shape of the anti-scattering bars along with the edges can be rectangular.

FIG. 5C shows a cross-sectional view of the mask of FIG. 5B after the layer of opaque material has been etched. As shown in FIG. 5C, the parts of anti-scattering bars and square holes of the layer of opaque material not covered by the photo-resist layer 42 are etched away using either wet or dry isotropic etching, preferably wet isotropic etching, following methods well established in mask fabrication technology. After this process, a patterned layer of opaque material 20a is formed exposing four anti-scattering bars in the middle of the edge of the square, a square opening 14 at the center of the square and/or the square holes at the corners of the square.

FIG. 5D shows a cross-sectional view of the mask of FIG. 5C after the first photo-resist layer 42 has been removed. As shown in FIG. 5D, the remaining first photo-resist layer is then removed.

FIG. 5E shows a cross-sectional view of the mask of FIG. 5D with a patterned layer of opaque material 20a and a second photo-resist layer 44 formed thereon. As shown in FIG. 5E, a second photo-resist layer is deposited on the patterned layer of opaque material 20a.

FIG. 5F shows a cross-sectional view of the mask of FIG. 5E after the second photo-resist layer 44 has been exposed and developed. As shown in FIG. 5F, the second photo-resist layer 44 is then developed. The exposure of the second photo-resist layer is such that after developing the second photo-resist layer, the pattern is formed exposing the square holes 46a and 46b of the square.

FIG. 5G shows a cross-sectional view of the mask of FIG. 5F after the mask substrate has been etched. As shown in FIG. 5G, the parts of square holes of the layer of mask substrate 18 not covered by the photo-resist layer are etched away using dry etching following methods well established in mask fabrication technology. After this process, the square holes 12a, 12b, 12c, and 12d at the corners of the square are formed.

FIG. 5H shows a cross-sectional view of the mask of FIG. 5G after the second photo-resist layer has been removed. As shown in FIG. 5H, the remaining photo-resist layer is then removed and the mask is completed. The mask design data is used to determine which sections of the mask are formed as square holes and which sections of the mask will have square openings formed without opaque material.

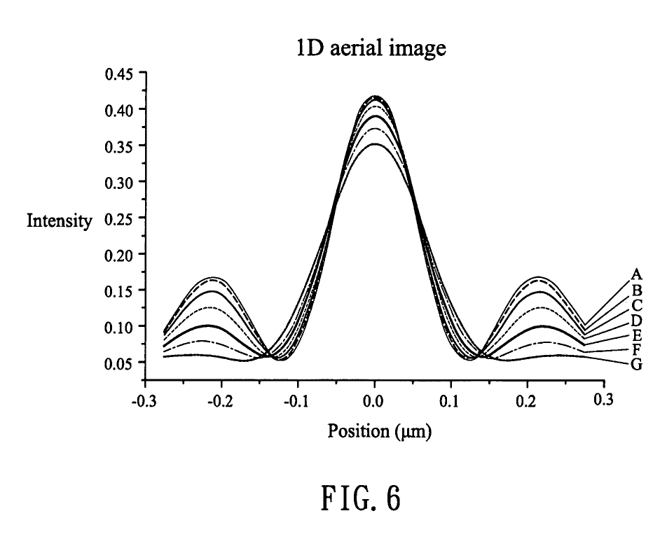

FIG. 6 shows aerial images of simulation for isolated patterns of the mask of the invention. There are seven curves in the figure. It is found that using the mask of the invention reduces the intensity drop caused by the defocus. Therefore it improves the process window for exposing the pattern of the contact hole.

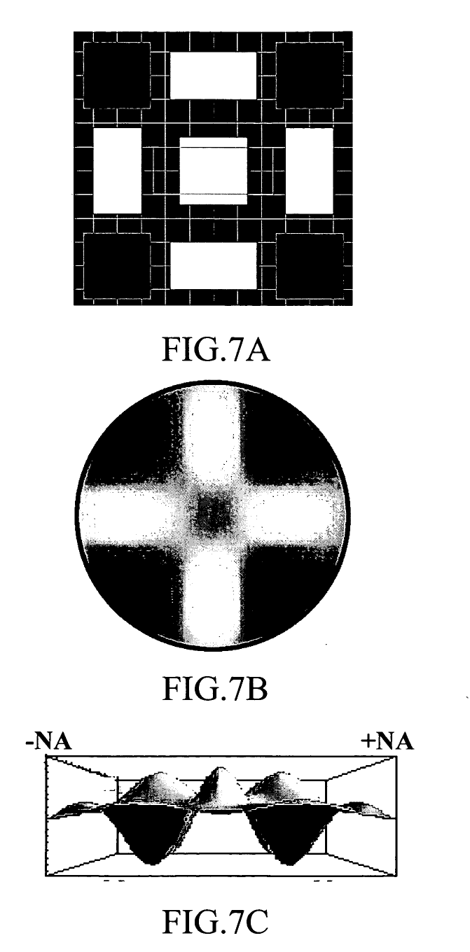

FIG. 7B shows the Fourier Transform distribution image of the mask of the FIG. 7A. Further, FIG. 7C shows the cross-section view of the simulation corresponding to the Fourier Transform distribution image of FIG. 7B. According to the figures, it is found that the contrast ratio of the darkness region and the lightness region is better. Therefore, the differences between the darkness region and the lightness region make the intensity of the central contact hole pattern even strong.

As described above, illuminating the designed mask pattern having at least one pattern comprising four square contact holes at the corners of a square to produce phase shifting (180 degree), and a square opening at the center of the square and four anti-scattering bars around the central square opening to produce non-phase shifting (0 degree) with OAI can enhance the DOF of the process window for isolated and semi-isolated pitch contact hole patterns. Therefore, illuminating the mask of the invention can produce exposure energy latitude, larger depth of focus, and good contrast image for the pattern of contact holes on the semiconductor substrate.

While the invention has been described with reference to the preferred embodiments thereof, it will be understood by those skilled in the art that various changes in form and detail may be made without departing from the spirit and scope of the invention.

1. A mask, comprising:
a mask substrate;
at least one pattern on said mask substrate, wherein said pattern comprises a substantially square opening formed as a center of a square; a plurality of substantially square holes formed at the corners of the square respectively; and a plurality of anti-scattering bars formed around the square opening, each of the anti-scattering bars is located between two square holes and in the middle of one edge of the square; and
a layer of opaque material formed in a spacing between the square openings, the anti-scattering bar and the square hole.

2. The mask of claim 1, wherein said square hole forms by removing the layer of opaque material and the mask substrate.

3. The mask of claim 1, wherein said anti-scattering bar forms by removing the desired opaque material.

4. The mask of claim 1, wherein said square hole is a phase shifting region and said anti-scattering bar is a non phase shifting region.

5. The mask of claim 4, wherein said phase shifting region has 180 degree phase shifting.

6. The mask of claim 4, wherein said anti-scattering bar has 0 degree phase shifting.

7. The mask of claim 1, wherein said square opening has 0 degree phase shifting.

8. A method of manufacturing a mask, comprising:
providing a mask substrate;
forming a layer of opaque material on said mask substrate;
patterning the opaque material;
forming a square opening as a center of a square and a plurality of anti-scattering bars around the square opening, each of the anti-scattering bars is located in a middle of one edge of the square;
patterning said mask substrate; and
forming a plurality of square holes at corners of the square respectively.

9. The mask of claim 8, wherein said square hole forms by removing the layer of opaque material and the mask substrate.

10. The mask of claim 8, wherein said anti-scattering bar forms by removing the layer of opaque material.

11. The mask of claim 8, wherein said square hole is a phase shifting region and said anti-scattering bar is a non phase shifting region.

12. The mask of claim 11, wherein said phase shifting region has 180 degree phase shifting.

13. The mask of claim 11, wherein said anti-scattering bar has 0 degree phase shifting.

14. The mask of claim 11, wherein said square opening has 0 degree phase shifting.
